(19) United States
(12) Patent Application Publication
(10) Pub. No.: US 2025/0255090 A1
(43) Pub. Date: Aug. 7, 2025

(54) DISPLAY DEVICE AND ELECTRONIC DEVICE INCLUDING THE SAME

(71) Applicant: Samsung Display Co., LTD., Yongin-si (KR)

(72) Inventors: SEUNGHWA JEONG, Yongin-si (KR); JONGJANG PARK, Yongin-si (KR)

(21) Appl. No.: 19/047,568

(22) Filed: Feb. 6, 2025

(30) Foreign Application Priority Data
Feb. 7, 2024 (KR) 10-2024-0019212

(51) Int. Cl. H10K 50/115; H10K 59/80

(52) U.S. Cl. CPC H10K 50/115; H10K 59/8722

(57) ABSTRACT

A display device includes a first substrate, a display element layer disposed on the first substrate and including at least one pixel including a quantum dot, a first sealing member disposed on the first substrate and surrounding at least a portion of the display element layer, a second sealing member disposed on the first substrate and surrounding at least a portion of the first sealing member, and a second substrate disposed on the display element layer, the first sealing member, and the second sealing member.

This application claims priority to Korean Patent Application No. 10-2024-0019212, filed on Feb. 7, 2024, and all the benefits accruing therefrom under 35 U.S.C. § 119, the content of which in its entirety is herein incorporated by reference.

### BACKGROUND

### 1. Field

Embodiments relate to a display device. More particularly, the embodiments relate to a display device that provides visual information.

### 2. Description of the Related Art

As information technology develops, the importance of a display device, which is a connecting medium between users and information, is emerging. Accordingly, use of a display device such as, for example, a liquid crystal display device, an organic light-emitting display device, plasma display device, a quantum dot light-emitting display device, and the like is increasing.

The quantum dot light-emitting display device uses quantum dots as a light emitter and has advantages of high chromaticity, high luminous efficiency, and multi-coloring. There is a need for a method to improve a performance of the quantum dot light-emitting display device.

### SUMMARY

Embodiments provide a display device with an improved display quality.

A display device according to an embodiment includes a first substrate, a display element layer disposed on the first substrate and including at least one pixel including a quantum dot, a first sealing member disposed on the first substrate and surrounding at least a portion of the display element layer, a second sealing member disposed on the first substrate and surrounding at least a portion of the first sealing member, and a second substrate disposed on the display element layer, the first sealing member, and the second sealing member.

In an embodiment, the first sealing member may include a first material and the second sealing member may include a second material different from the first material.

In an embodiment, the second sealing member may include an acidic material.

In an embodiment, the second sealing member further may include a glass powder and a ceramic filler.

In an embodiment, wherein the glass powder may include at least one selected from a group consisting of a vanadium pentoxide (V₂O₅), a bismuth trioxide (Bi₂O₃), and a lead oxide (PbO).

In an embodiment, the acidic material further may include at least one selected from a group consisting of a methacrylic acid, an acrylic acid, and a citric acid.

In an embodiment, the second sealing member further may include a polymer resin.

In an embodiment, the first sealing member may include a poly acrylic acid (PAA).

In an embodiment, the first sealing member may be spaced apart from the display element layer.

In an embodiment, the second sealing member may be spaced apart from the first sealing member.

In an embodiment, the first sealing member entirely may surround an outer edge of the display element layer.

In an embodiment, the second sealing member entirely may surround an outer edge of the first sealing member.

In an embodiment, a width of the second sealing member may be larger than a width of the first sealing member.

In an embodiment, a height of the first sealing member and a height of the second sealing member may each be larger than a height of the display element layer.

In an embodiment, the first sealing member may contact the first substrate and the second substrate.

In an embodiment, the second sealing member may contact the first substrate and the second substrates.

A display device according to an embodiment includes a first substrate, a display element layer disposed on the first substrate and including at least one pixel including a quantum dot, a sealing member disposed on the first substrate, surrounding the display element layer, and including an acidic material, and a second substrate disposed on the display element layer and the sealing member.

In an embodiment, the sealing member may include a first sealing member surrounding at least a portion of the display element layer and a second sealing member surrounding at least a portion of the first sealing member.

In an embodiment, the second sealing member may include a glass powder and a ceramic filler.

In an embodiment, the acidic material may include at least one selected from a group consisting of a methacrylic acid, an acrylic acid, and a citric acid.

An electronic device according to an embodiment includes a processor outputting an image data signal and an input control signal and a display device configured driving based on the image data signal and the input control signal. The display device includes a first substrate, a display element layer disposed on the first substrate and comprising at least one pixel comprising a quantum dot, a first sealing member disposed on the first substrate and surrounding at least a portion of the display element layer, a second sealing member disposed on the first substrate and surrounding at least a portion of the first sealing member, and a second substrate disposed on the display element layer, the first sealing member, and the second sealing member.

In a display device according to embodiments of the present disclosure, the display device may include a first substrate, a display element layer disposed on the first substrate, a first sealing member surrounding at least a portion of the display element layer, a second sealing member surrounding at least a portion of the first sealing member, and a second substrate disposed on the first substrate, the first sealing member, and the second sealing member. Accordingly, embodiments of the present disclosure support easily performing a positive aging process in which a hydrogen ion and/or a water emitted from the first sealing member and the second sealing member is supplied to an interlayer.

In some aspects, the first sealing member may contact both of the first substrate and the second substrate. Accordingly, embodiments of the present disclosure support the prevention or reduction of a peeling phenomenon in which the second sealing member separates from the first substrate.

In some aspects, the first sealing member may be spaced apart from the second sealing member. Accordingly, the first sealing member may partially contact a portion of the second substrate. Accordingly, as the first sealing member partially contacts the second substrate, embodiments of the present disclosure support manufacturing a display device without implementing an additional process such as, for example, a plasma treatment compared to when the first sealing member entirely contacts the second substrate. Accordingly, for example, embodiments of the present disclosure support a reduced processing time and a reduced processing cost for manufacturing a display device compared to other approaches.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of present disclosure.

FIG. 2 is a cross-sectional view illustrating a cross-section taken along a line I-I′ of FIG. 1.

FIG. 3 is an enlarged cross-sectional view illustrating an area A of FIG. 2.

FIG. 4 is a cross-sectional view illustrating a cross-section taken along a line II-II′ of FIG. 1.

FIG. 5 is a cross-sectional view illustrating a first interlayer of FIG. 4.

FIG. 6 is a block diagram of an electronic device according to an embodiment of the present disclosure.

FIG. 7 is a schematic diagram of the electronic device according to various embodiments of the present disclosure.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

Embodiments supported by the present disclosure will now be described more fully hereinafter with reference to the accompanying drawings, in which one or more example embodiments are shown. Aspects supported by the present disclosure may, however, be embodied in different forms and should not be construed as limited to the embodiments set forth herein. Rather, these example embodiments are provided such that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually equal (e.g., within a threshold percent of equal). The term “substantially simultaneously” means approximately or actually at the same time (e.g., within a threshold percent of equal). The term “substantially the same” means approximately or actually the same (e.g., within a threshold difference amount).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

Embodiments of the present disclosure support one or more processes (methods, flowcharts) supportive of the features and embodiments described herein. Descriptions that an element “may be disposed,” “may be formed,” “may be arranged,” “may be performed,” and the like include processes (methods, flowcharts) and techniques for manufacturing, disposing, forming, positioning, and modifying the element and the like in accordance with example aspects described herein.

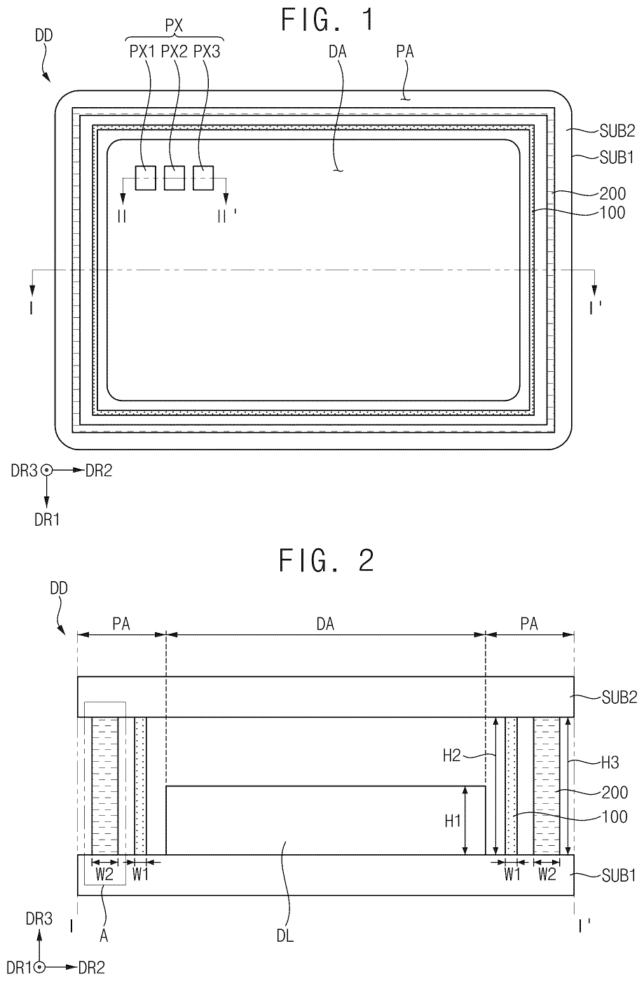

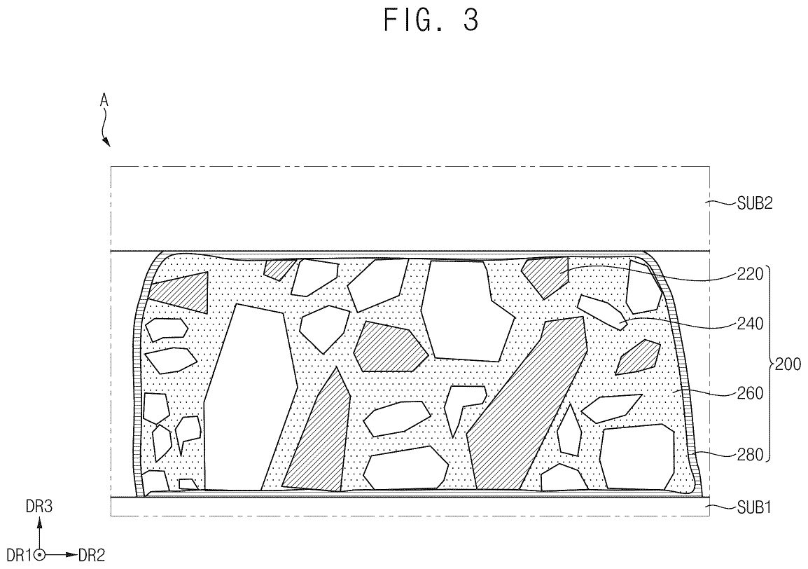

FIG. 1 is a plan view illustrating a display device according to an embodiment of present disclosure. FIG. 2 is a cross-sectional view illustrating a cross-section taken along a line I-I′ of FIG. 1. FIG. 3 is an enlarged cross-sectional view illustrating an area A of FIG. 2.

Referring to FIGS. 1, 2, and 3, a display device DD according to an embodiment of present disclosure may include a display area DA and a peripheral area PA. The display area DA may be an area which generates images, and the peripheral area PA may be an area which does not generate images.

At least one pixel PX may be disposed in the display area DA. The pixel PX may include a first pixel PX1, a second pixel PX2, and a third pixel PX3. The first pixel PX1, the second pixel PX2, and the third pixel PX3 may be referred to herein as sub-pixels. For example, the first pixel PX1 may emit first light, the second pixel PX2 may emit second light, and the third pixel PX3 may emit third light. In an embodiment, the first light may be red light, the second light may be green light, the third light may be blue light. However, embodiments of the present disclosure are not limited thereto. For example, a plurality of pixels PX may be combined to emit yellow, cyan, and magenta light.

The first, second, and third pixels PX1, PX2, and PX3 may be repeatedly arranged along a first direction DR1 and a second direction DR2 intersecting with the first direction DR1 in a plan view. For example, the second pixel PX2 may be adjacent to the first pixel PX1 in the second direction DR2. In some aspects, the third pixel PX3 may be adjacent to the second pixel PX2 in the second direction DR2.

The peripheral area PA may be located around the display area DA. For example, the peripheral area PA may surround at least a portion of the display area DA. A driver may be disposed in the peripheral area PA. The driver may provide a signal or a voltage to the pixel PX. For example, the driver may include a data driver, a gate driver, and the like.

The display device DD may include a first substrate SUB1, a display element layer DL, a first sealing member 100, a second sealing member 200, and a second substrate SUB2.

The first substrate SUB1 may be a base of the display device DD. In an embodiment, the first substrate SUB1 may include glass, quartz, a plastic, and the like. The materials may be used alone or in combination with each other.

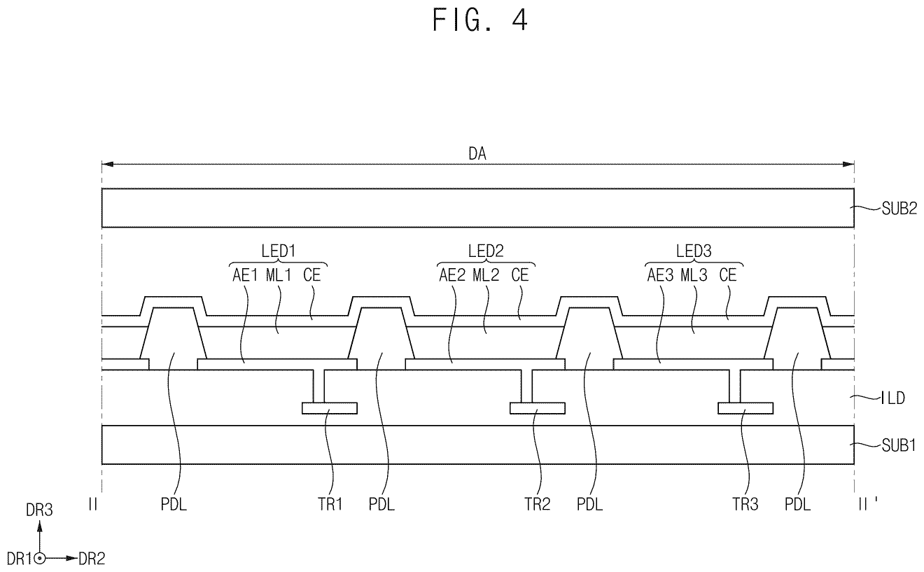

The display element layer DL may be disposed on the first substrate SUB1. The display element layer DL may include one or more pixels PX. Accordingly, the display element layer DL may display images, and may define the display area DA of the display device DD. In other words, an area where the display element layer DL is disposed on the first substrate Sub1 may be the display area DA, and the area where the display element layer DL is not disposed may be the peripheral area PA. That is, the display element layer DL may overlap the display area DA in a third direction DR3, and may not overlap the peripheral area PA in the third direction DR3. A specific structure of the display element layer DL will be described later with reference to FIG. 4.

The first sealing member 100 may be disposed on the first substrate SUB1. The first sealing member 100 may be disposed in the peripheral area PA. The first sealing member 100 may surround at least a portion of the display element layer DL. In an embodiment, the first sealing member 100 may entirely surround an outer edge of the display element layer DL. In another embodiment, the first sealing member 100 may surround a portion of the display element layer DL.

In an embodiment, the first sealing member 100 may have a rectangular shape in a plan view. However, embodiments of the present disclosure are not limited thereto, and a shape of the first sealing member 100 may have various shapes such as, for example, a polygonal or circular shape in a plan view.

In an embodiment, the first sealing member 100 may include an acidic material. For example, the acidic material may include poly acrylate acid (PAA). However, a type of the acidic material included in the first sealing member 100 according to embodiments of the present disclosure are not limited thereto, and various acidic materials which supply a hydrogen ion (H⁺) and/or a water (H₂O) to the display element layer DL may be included in the first sealing member 100. Accordingly, embodiments of the present disclosure may include supplying the hydrogen ion (H⁺) and/or water (H₂O) emitted from the first sealing member 100 to the display element layer DL without directly applying an acidic material to the display element layer DL.

In an embodiment, the first sealing member 100 may be spaced apart from the display element layer DL. In other words, the first sealing member 100 may not contact the display element layer DL. Specifically, the first sealing member 100 may be spaced apart from each of the first, second, and third pixels PX1, PX2, and PX3.

The second sealing member 200 may be disposed on the first substrate SUB1. The second sealing member 200 may be disposed in the peripheral area PA. The second sealing member 200 may surround at least a portion of the first sealing member 100. In an embodiment, the second sealing member 200 may entirely surround the first sealing member 100. In another embodiment, the second sealing member 200 may surround a portion of the first sealing member 100.

In an embodiment, the second sealing member 200 may have a rectangular shape in a plan view. However, embodiments of the present disclosure are not limited thereto, and a shape of the second sealing member 200 may have various shapes such as, for example, a polygonal or a circular shape in a plan view.

In an embodiment, the second sealing member 200 may be formed along an outer edge of the first sealing member 100 such that a constant distance is maintained between the second sealing member 200 and the first sealing member 100. However, embodiments of the present disclosure are not limited thereto, and the distance between the second sealing member 200 and the first sealing member 100 may vary (e.g., may not be constant).

In an embodiment, a shape of the second sealing member 200 and a shape of the first sealing member 100 may be the same in a plan view. For example, the shape of the first sealing member 100 and the shape of the second sealing member 200 may both have a rectangular shape in a plan view. However, embodiments of the present disclosure are not limited thereto, and the shape of the first sealing member 100 and the shape of the second sealing member 200 may be different from each other in a plan view. For example, the shape of the second sealing member 200 may have a polygonal shape, and the shape of the first sealing member 100 may have a circular shape in a plan view.

In an embodiment, a hydrogen plasma treatment may be performed on the first sealing member 100. Accordingly, an amount of the hydrogen ion emitted from the first sealing member 100 may be increased.

In an embodiment, the second sealing member 200 may be spaced apart from the first sealing member 100. For example, the second sealing member 200 may be spaced apart from the first sealing member 100 in a plane parallel to the first substrate SUB1. Specifically, a portion of the second sealing member 200 extending in the first direction DR1 and a portion of the first sealing member 100 extending in the first direction DR1 may be spaced apart in the second direction DR2. In some aspects, a portion of the second sealing member 200 extending in the second direction DR2 and a portion of the first sealing member 100 extending in the second direction DR2 may be spaced apart in the first direction DR1. In other words, the second sealing member 200 may not contact the first sealing member 100.

In an embodiment, the second sealing member 200 may include an acidic material. For example, the acidic substance may include a methacrylic acid, an acrylic acid, a citric acid, and the like. The acids may be used alone or in combination with each other. However, a type of the acidic material included in the second sealing member 200 according to embodiments of the present disclosure are not limited thereto, and various types of acidic materials which supply a hydrogen ion to the display element layer DL may be included in the second sealing member 200.

As illustrated in FIG. 3, the second sealing member 200 may further include a ceramic filler 220 and a glass powder 240. For example, the second sealing member 200 may form a frit through the ceramic filler 220 and the glass powder 240.

The ceramic filler 220 may include fillers having various shapes located in the second sealing member 200. The fillers may be spaced apart from each other in the second sealing member 200. In an embodiment, shape and arrangement of the fillers may be irregular. However, in the present disclosure, the shape and arrangement of the fillers are not limited thereto, and the shape and arrangement of the fillers may be regular. A mechanical strength of the second sealing member 200 may be improved through the ceramic filler 220.

The glass powder 240 may include a glass material. The organic material may include a vanadium pentoxide (V₂O₅), a bismuth trioxide (Bi₂O₃), a lead oxide (PbO), and the like. The materials may be used alone or in combination with each other.

The glass powder 240 may be disposed such that the glass powder 240 is spaced apart from the ceramic filler 220. In some aspects, the glass powder 240 may include powders of various shapes located in the second sealing member 200. The powders may be spaced apart from each other in the second sealing member 200. In an embodiment, shape and arrangement of the powders may be irregular. However, in the present disclosure, the shape of the fillers is not limited thereto, and the shape of the fillers may be regular.

In an embodiment, the second sealing member 200 may further include a polymer resin 260. The polymer resin 260 may have a viscosity. For example, the polymer resin 260 may bind the ceramic filler 220 and the glass powder 240 included in the second sealing member 200 to each other. The polymer resin 260 may include an ethyl cellulose (EC). However, embodiments of the present disclosure are not limited thereto, and may include various types of polymer resins bonding the ceramic filler 220 and the glass powder 240 included in the second sealing member 200 to each other. In an embodiment, the second sealing member 200 may further include a solvent dissolving the polymer resin 260.

In an embodiment, the first sealing member 100 and the second sealing member 200 may include a different material from each other. For example, the first sealing member 100 may include a first material, and the second sealing member 200 may include a second material different from the first material. In an example, the first sealing member 100, unlike the second sealing member 200, may not include the ceramic filler 220, the glass powder 240, and the polymer resin 260.

A surface 280 of the second sealing member 200 may surround the ceramic filler 220, glass powder 240, and polymer resin 260. The surface 280 of the second sealing member 200 may contact the first and second substrates SUB1 and SUB2. In some aspects, an acidic material may be applied to the surface 280 of the second sealing member 200. In some aspects, a speed at which a hydrogen ion included in the acidic material are supplied to the display element layer DL may be improved through a post-bake process.

In an embodiment, hydrogen plasma treatment may be performed on the second sealing member 200. Accordingly, the amount of the hydrogen ion emitted from the second sealing member 200 may be increased.

In an embodiment, an area of the second sealing member 200 may be relatively larger than an area of the first sealing member 100 in a plan view parallel to the first substrate SUB1. Specifically, a width W2 in the second direction DR2 of a portion of the second sealing member 200 extending in the first direction DR1 may be larger than a width W1 in the second direction DR2 of a portion of first sealing member 100 extending in the first direction DR1. In some aspects, when the display device DD is cut along a line parallel to the first direction DR1, a width in the first direction DR1 of a portion of the second sealing member 200 extending in the second direction DR2 may be larger than a width in the first direction DR1 of a portion of the first sealing member 100 extending in the second direction DR2.

However, embodiments of the present disclosure are not limited thereto, and in a plane, an area of the second sealing member 200 may be relatively smaller than an area of the first sealing member 100, or the area of the second sealing member 200 may be the same as (e.g., equal to, the same shape, or the like) the area of the first sealing member 100. For example, the width W2 in the second direction DR2 of the portion of the second sealing member 200 extending in the first direction DR1 may be smaller than the width W1 in the second direction DR2 of the portion of first sealing member 100 extending in the first direction DR1. Alternatively, the width W2 in the second direction DR2 of the portion of the second sealing member 200 extending in the first direction DR1 may be the same as the width W1 in the second direction DR2 of the portion of first sealing member 100 extending in the first direction DR1.

In an embodiment, a height H2 of the first sealing member 100 may be larger than a height H1 of the display element layer DL. In some aspects, a height H3 of the second sealing member 200 may be larger than the height H1 of the display element layer DL. Each of the height H2 of the first sealing member 100 and the height H3 of the second sealing member 200 may be a distance between the first substrate SUB1 and the second substrate SUB2. As the display element layer DL does not contact the first substrate SUB1 and the second substrate SUB2, and the display element layer DL is spaced apart from each of the first sealing member 100 and the second sealing member 200, each of the height H2 of the first sealing member 100 and the height H3 of the second sealing member 200 may be larger than the height H1 of the display element layer DL.

In an embodiment, the height H2 of the first sealing member 100 and the height H3 of the second sealing member 200 may be substantially the same. In another embodiment, the height H2 of the first sealing member 100 and the height H3 of the second sealing member 200 may be different from each other.

The second substrate SUB2 may be disposed on the first substrate SUB1. The second substrate SUB2 may be disposed on the first sealing member 100, the second sealing member 200, and the display element layer DL. For example, the second substrate SUB2 may cover the display element layer DL. Specifically, the second substrate SUB2 may be an encapsulation substrate that protects the display element layer DL. For example, the second substrate SUB2 may include glass.

The second substrate SUB2 may be disposed such that the second substrate SUB2 overlaps the first substrate SUB1. The second substrate SUB2 and the first substrate SUB1 may face each other. Specifically, a rear surface of the second substrate SUB2 may face an upper surface of the first substrate SUB1. In some aspects, the second substrate SUB2 and the first substrate SUB1 may face each other and be spaced apart in the third direction DR3.

The second substrate SUB2 may cover the first sealing member 100 and the second sealing member 200. The second substrate SUB2 may contact each of the first sealing member 100 and the second sealing member 200. For example, a portion of the second substrate SUB2 may contact an upper surface of the first sealing member 100. A portion of the second substrate SUB2 may contact an upper surface of the second sealing member 200. Accordingly, the first sealing member 100 and the second sealing member 200 may bond the first substrate SUB1 and the second substrate SUB2. In some aspects, the first substrate SUB1 and the second substrate SUB2 may be spaced apart from each other due to the first sealing member 100 and the second sealing member 200.

In an embodiment, during a manufacturing process of the display device DD, the second sealing member 200 may be formed on the first substrate SUB1. After the second sealing member 200 is formed on the first substrate SUB1, the display device DD may be manufactured by bonding the second substrate SUB2 and the first substrate SUB1. In other words, the second sealing member 200 may not be formed on the second substrate SUB2, and as the second substrate SUB2 and the first substrate SUB1 are bonded, the second sealing member 200 may contact the second substrate SUB2. However, embodiments of the present disclosure are not limited thereto.

FIG. 4 is a cross-sectional view illustrating a cross-section taken along a line II-II′ of FIG. 1.

Referring to FIG. 4, the display device DD may include the first substrate SUB1, a first driving element TR1, a second driving element TR2, and a third driving element TR3, an insulating structure ILD, a pixel defining layer PDL, a first pixel electrode AE1, a second pixel electrode AE2, a third pixel electrode AE3, a first interlayer ML1, a second interlayer ML2, a third interlayer ML3, a common electrode CE, and a second substrate SUB2.

The display element layer DL of FIG. 2 may include the first driving element TR1, the second driving element TR2, the third driving element TR3, the insulating structure ILD, the pixel defining layer PDL, the first pixel electrode AE1, the second pixel electrode AE2, the third pixel electrode AE3, the first interlayer ML1, the second interlayer ML2, the third interlayer ML3, and the common electrode CE.

The first pixel PX1 of FIG. 1 may be formed as the first driving element TR1, the first pixel electrode AE1, the first interlayer ML1, and the common electrode CE. In some aspects, the second pixel PX2 of FIG. 1 may be formed as the second driving element TR2, the second pixel electrode AE2, the second interlayer ML2, and the common electrode CE. In some aspects, the third pixel PX3 of FIG. 1 may be formed as the third driving element TR3, the third pixel electrode AE3, the third interlayer ML3, and the common electrode CE.

The first, second, and third driving elements TR1, TR2, and TR3 may be disposed in the display area DA on the first substrate SUB1. Each of the first, second, and third driving elements TR1, TR2, and TR3 may include at least one transistor. A channel layer of the transistor may include an oxide semiconductor, a silicon semiconductor, an organic semiconductor, or the like.

The insulating structure ILD may be disposed on the first substrate SUB1. The insulating structure ILD may cover the first, second, and third driving elements TR1, TR2, and TR3. The insulating structure ILD may include at least one inorganic layer and at least one organic layer. The inorganic layer may include an inorganic insulating material. For example, the inorganic insulating material may include a silicon oxide, silicon nitride, silicon oxynitride, or the like. The materials may be used alone or in combination with each other. The organic insulating layer may include an organic material. For example, the organic insulating material may include a polyimide-based resin, a polyamide-based resin or the like. The materials may be used alone or in combination with each other.

The first, second, and third pixel electrodes AE1, AE2, and AE3 may be disposed on the insulating structure ILD. Each of the first, second, and third pixel electrodes AE1, AE2, and AE3 may include a conductive material such as, for example, a metal, an alloy, a conductive metal nitride, a conductive metal oxide, or a transparent conductive material. Each of the first, second, and third pixel electrodes AE1, AE2, and AE3 may have a single-layer structure or a multi-layer structure including a plurality of conductive layers.

The first, second, and third pixel electrodes AE1, AE2, and AE3 may be electrically connected to the first, second, and third driving elements TR1, TR2, and TR3, respectively, through contact holes formed in the insulating structure ILD.

The pixel defining layer PDL may be disposed on the first, second, and third pixel electrodes AE1, AE2, and AE3. The pixel defining layer PDL may define a pixel opening that exposes at least a portion of each of the first, second, and third pixel electrodes AE1, AE2, and AE3.

The pixel defining layer PDL may include an organic insulating material. For example, the organic insulating material may include a photoresist, a polyacryl-based resin, a polyimide-based resin, a polyamide-based resin, a siloxane-based resin, and an acryl-based resin, an epoxy-based resin, or the like. The materials may be used alone or in combination with each other.

The first, second, and third interlayers ML1, ML2, and ML3 may be disposed on the first, second, and third pixel electrodes AE1, AE2, and AE3 exposed by the pixel openings of the pixel defining layer PDL. Specifically, the first interlayer ML1 may be disposed on the first pixel electrode AE1. The second interlayer ML2 may be disposed on the second pixel electrode AE2. The third interlayer ML3 may be disposed on the third pixel electrode AE3.

The first interlayer ML1 may include a material that emits the first light, the second interlayer ML2 may include a material that emits the second light, and the third interlayer ML3 may include the material that emits the third light. As described herein, the first light may be blue light, the second light may be red light, and the third light may be green light. However, embodiments of the present disclosure are not limited thereto.

The common electrode CE may be disposed on the pixel defining layer PDL, the first interlayer ML1, the second interlayer ML2, and the third interlayer ML3. For example, the common electrode CE may entirely cover the pixel defining layer PDL, the first interlayer ML1, the second interlayer ML2, and the third interlayer ML3. The common electrode CE may include a conductive material such as, for example, a metal, alloy, a conductive metal nitride, a conductive metal oxide, or a transparent conductive material.

The first pixel electrode AE1, the first interlayer ML1, and the common electrode CE may form the first light-emitting element LED1 together. The second pixel electrode AE2, the second interlayer ML2, and the common electrode CE may together form the second light-emitting element LED2. The third pixel electrode AE3, the third interlayer ML3, and the common electrode CE may together form the third light-emitting element LED3.

The second substrate SUB2 may be disposed on the common electrode CE. A partition structure may be disposed in a space between the second substrate SUB2 and the common electrode CE. The partition structure may separate the second substrate SUB2 and the common electrode CE from each other. In other words, the partition structure may separate the display element layer DL and the second substrate SUB2 of FIG. 2 from each other. However, embodiments of the present disclosure are not limited thereto, and members except for the partition structure may be disposed in the space between the display element layer DL and the second substrate SUB2 of FIG. 2. Alternatively, or additionally, an air layer or a vacuum layer may be formed in the space between the display element layer DL and the second substrate SUB2.

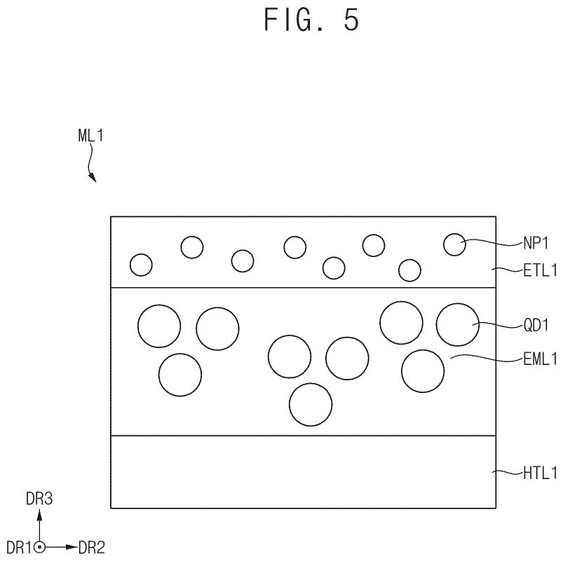

FIG. 5 is a cross-sectional view illustrating a first interlayer of FIG. 4.

Referring to FIG. 5, the first interlayer ML1 may include a first hole auxiliary layer HTL1, a first light-emitting layer EML1, and a first electron auxiliary layer ETL1.

The first hole auxiliary layer HTL1 may be disposed on the first pixel electrode AE1, the second pixel electrode AE2, the third pixel electrode AE3 of FIG. 4. For example, the first hole auxiliary layer HTL1 may include a hole injection layer and/or a hole transport layer. However, embodiments of the present disclosure are not limited thereto. For example, the first hole auxiliary layer HTL1 may further include a buffer layer or an electron blocking layer. The buffer layer may serve to increase a light-emitting efficiency by compensating for an optical resonance distance based on the wavelength of light emitted from the first light-emitting layer EML1. In some aspects, the electron blocking layer may serve to prevent electron injection from the first electron auxiliary layer ETL1.

The first light-emitting layer EML1 may be disposed on the first hole auxiliary layer HTL1. The first light-emitting layer EML1 may include a first quantum dot QD1 and a base resin. The first quantum dot QD1 may emit light when stimulated by light. By adjusting a composition and/or a size of the first quantum dot QD1, an absorption and a light-emitting wavelength of the first quantum dot QD1 may be adjusted. The first quantum dot QD1 may be disposed in the base resin. The base resin may include a polymer resin, a resin, or the like. However, materials included in the base resin in embodiments of the present disclosure are not limited thereto.

In an embodiment, the first quantum dot QD1 is a group II-VI semiconductor compound, a group III-VI semiconductor compound, a group III-V semiconductor compound, a group IV-VI semiconductor compound, a group IV element or compound, and a group I-III-VI semiconductor compounds, or the like. The compounds may be used alone or in combination with each other.

The II-VI group semiconductor compounds may include binary compounds such as, for example, CdS, CdSe, CdTe, ZnS, ZnSe, ZnTe, ZnO, HgS, HgSe, HgTe, MgS, MgSe, and the like; ternary compounds such as, for example, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe MgZnS, MgZnSe, and the like; quaternary compounds such as, for example, CdZnSeS, CdZnSeTe, CdZnSTe, CdHgSeS, CdHgSeTe, CdHgSTe, HgZnSeS, HgZnSeTe, HgZnSTe, and the like; or any combination thereof.

The III-VI group semiconductor compounds may include binary compounds such as, for example, In2S3, Ga2S3, and the like; Tri-element compounds such as, for example, InGaS3, InGaSe3, and the like; or any combination thereof.

The III-V group semiconductor compounds include binary compounds such as, for example, GaN, GaP, GaAs, GaSb, AlN, AIP, AlAs, AlSb, InN, InP, InAs, InSb, and the like; ternary compounds such as, for example, GaNP, GaNAs, GaNSb, GaPAs, GaPSb, AlNP, AlNAs, AlNSb, AlPAs, AlPSb, InAsP, InGaP, InGaAs, InAlP, InNP, InNAs, InNSb, InPAs, InPSb, GaAlNP, and the like; quaternary compounds such as, for example, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the like; or any combination thereof. The group III-V semiconductor compound may further include a group II metal (e.g., InZnP, and the like.) The IV-VI group compounds include binary compounds such as, for example, SnS, SnSe, SnTe, PbS, PbSe, PbTe, and the like; ternary compounds such as, for example, SnSeS, SnSeTe, SnSTe, PbSeS, PbSeTe, PbSTe, SnPbS, SnPbSe, SnPbTe, and the like; quaternary compounds such as, for example, SnPbSSe, SnPbSeTe, SnPbSTe, and the like; or any combination thereof.

The Group IV element or a compound containing the Group IV element is Si and/or Ge; binary compounds such as, for example, SiC, SiGe, and the like; or any combination thereof.

The Group I-III-VI semiconductor compounds include ternary compounds such as, for example, AgInS, AgInS2, CuInS, CuInS2, CuGaO2, AgGaO2, and AgAlO2; or any combination thereof. The Group I-III-VI semiconductor compound may further include a group II element. For example, the group I-III-VI semiconductor compound may include quaternary compounds such as, for example, CuInZnS.

The first quantum dot QD1 may have a single structure with homogeneous components and composition, or a complex structure such as, for example, a core-shell structure, a gradient structure, and the like.

The first electron auxiliary layer ETL1 may be disposed on the first light-emitting layer EML1. The first electron auxiliary layer ETL1 may include an electron transport layer and/or an electron injection layer. However, embodiments of the present disclosure are not limited thereto. For example, the first electron auxiliary layer ETL1 may further include an electron blocking layer. The electron blocking layer may serve to prevent hole injection from the first electron auxiliary layer ETL1.

In an embodiment, the first electron auxiliary layer ETL1 may include a first nanoparticle NP1. In an embodiment, the first nanoparticle NP1 may include metal oxide. For example, the metal oxide may include a zinc oxide (ZnO), a zinc magnesium oxide (ZnMgO), or the like. The materials may be used alone or in combination with each other.

However, the first interlayer ML1 is illustrated as a structure in which the first hole auxiliary layer HTL1, the first light-emitting layer EML1, and the first electron auxiliary layer ETL1 are stacked in that order, but embodiments of the present disclosure are not limited thereto. Alternatively, the first interlayer ML1 may have an inverted structure in which the first electron auxiliary layer ETL1, the first light-emitting layer EML1, and the first hole auxiliary layer HTL1 are stacked in that order.

Although FIG. 5 illustrates a structure of the first interlayer ML1, respective structures of the second and third interlayers ML2 and ML3 of FIG. 4 may be substantially the same as the structure of the first interlayer ML1, and repeated descriptions of like elements are omitted for brevity.

However, further referring to FIGS. 1, 2, and 3, embodiments of the present disclosure support a positive aging, which is a process that removes a defect formed in the first nanoparticle NP1 by supplying the hydrogen ion and/or the water to the first nanoparticle NP1 included in the first electron auxiliary layer ETL1. Accordingly, a luminous efficiency of the display device DD may be improved. The water is a medium for supplying the hydrogen ion, and the hydrogen ion and water supplied to the first nanoparticle NP1 may diffuse in a gaseous form.

As described herein, the display device DD may include the first sealing member 100 and the second sealing member 200 including an acidic material. Accordingly, embodiments of the present disclosure may include performing the positive aging in which the hydrogen ion and/or the water emitted from the first sealing member 100 and the second sealing member 200 are supplied to the first, second, and third interlayers ML1, ML2, and ML3 of the display element layer DL. Specifically, the hydrogen ion and/or the water may be supplied to the first electron auxiliary layer ETL1, the second electron auxiliary layer, and the third electron auxiliary layer.

In some aspects, the first sealing member 100 may be in contact with both the first substrate SUB1 and the second substrate SUB2. Accordingly, the second sealing member 200 is separated from the first substrate SUB1. can be prevented.

In some aspects, the first sealing member 100 and the second sealing member 200 may be spaced apart from each other on the first substrate SUB1. Accordingly, the first sealing member 100 may partially contact a portion of the second substrate SUB2. Accordingly, as the first sealing member 100 partially contacts the second substrate SUB2, embodiments of the present disclosure support manufacturing a display device DD without implementing an additional process such as, for example, plasma treatment compared to when the first sealing member 100 entirely contacts the second substrate SUB2. Accordingly, for example, embodiments of the present disclosure support a reduced processing time and a reduced processing cost for manufacturing a display device DD compared to other approaches.

The display device according to the embodiment may be applied to various electronic devices. An electronic device according to an embodiment of the present disclosure may include the display device (e.g., the display device DD of FIG. 1) described above, and may further include modules or devices having additional functions in addition to the display device.

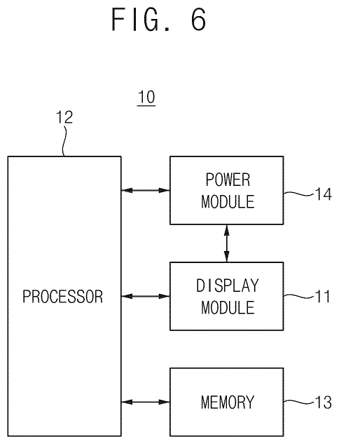

FIG. 6 is a block diagram of an electronic device according to an embodiment of the present disclosure.

Referring to FIG. 6, an electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process a signal received and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device according to the embodiments described above. In addition, a part among the individual modules functionally included in one module may be included in the display device, and another part may be provided separately from the display device. For example, the display device may include the display module 11, and the processor 12, the memory 13, and the power module 14 may be provided in the form of other devices within the electronic device 10 except for the display device.

In an embodiment, the display module 11 included in the display device may drive based on the image data signal and the input control signal received from the processor 12.

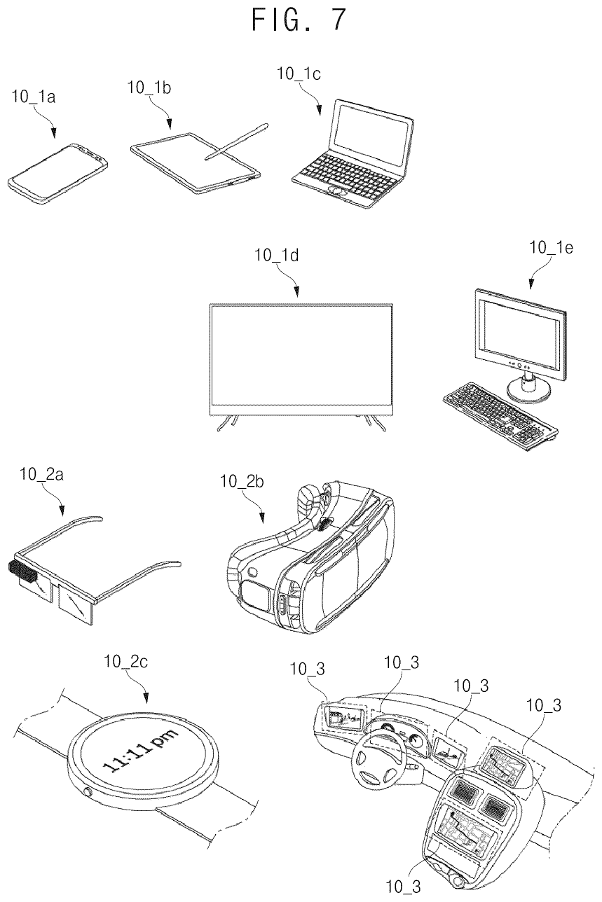

In an embodiment, the electronic device 10 may further include a sensor module, a camera module, an audio output module, and/or the like. For example, the sensor may include an optical sensor module, a touch sensor module, an acceleration sensor module, proximity sensor module, a pupil sensor module, an infrared sensor module, a light sensor module, an optical sensor module, and/or the like. In an embodiment, each of the sensor module, the camera module and the audio output module may be electrically connected to the processor 12. FIG. 7 is a schematic diagram of the electronic device according to various
embodiments.

Referring to FIG. 7, various electronic devices to which display devices according to embodiments are applied may include not only image display electronic devices such as a smart phone 10_1a, a tablet PC 10_1b, a laptop 10_1c, a TV 10_1d, and a desk monitor 10_1, but also a wearable electronic device including display modules such as smart glasses 10_2a, a head mounted display 10_2b, and a smart watch 10_2c, and a vehicle electronic device 10_3 including a dashboard, a center fascia, and display modules such as a CID (Center Information Display) and a room mirror display disposed in the dashboard.

The device according to the example embodiments described herein may be applied to an electronic device included in a computer, a notebook, a mobile phone, a smartphone, a smart pad, a PMP, a PDA, an MP3 player, or the like.

Although the device according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a first substrate;
a display element layer disposed on the first substrate and comprising at least one pixel comprising a quantum dot;
a first sealing member disposed on the first substrate and surrounding at least a portion of the display element layer;
a second sealing member disposed on the first substrate and surrounding at least a portion of the first sealing member; and
a second substrate disposed on the display element layer, the first sealing member, and the second sealing member.

2. The display device of claim 1, wherein the first sealing member comprises a first material and the second sealing member comprises a second material different from the first material.

3. The display device of claim 1, wherein the second sealing member comprises an acidic material.

4. The display device of claim 3, wherein the second sealing member further comprises a glass powder and a ceramic filler.

5. The display device of claim 4, wherein the glass powder comprises at least one selected from a group consisting of a vanadium pentoxide (V₂O₅), a bismuth trioxide (Bi₂O₃), and a lead oxide (PbO).

6. The display device of claim 3, wherein the acidic material further comprises at least one selected from a group consisting of a methacrylic acid, an acrylic acid, and a citric acid.

7. The display device of claim 3, wherein the second sealing member further comprises a polymer resin.

8. The display device of claim 1, wherein the first sealing member comprises a poly acrylic acid (PAA).

9. The display device of claim 1, wherein the first sealing member is spaced apart from the display element layer.

10. The display device of claim 1, wherein the second sealing member is spaced apart from the first sealing member.

11. The display device of claim 1, wherein the first sealing member entirely surrounds an outer edge of the display element layer.

12. The display device of claim 1, wherein the second sealing member entirely surrounds an outer edge of the first sealing member.

13. The display device of claim 11, wherein a width of the second sealing member is larger than a width of the first sealing member.

14. The display device of claim 1, wherein a height of the first sealing member and a height of the second sealing member are each larger than a height of the display element layer.

15. The display device of claim 1, wherein the first sealing member contacts the first substrate and the second substrate.

16. The display device of claim 1, wherein the second sealing member contacts the first substrate and the second substrate.

17. A display device comprising:
a first substrate;
a display element layer disposed on the first substrate and comprising at least one pixel comprising a quantum dot;
a sealing member disposed on the first substrate, surrounding the display element layer, and comprising an acidic material; and
a second substrate disposed on the display element layer and the sealing member.

18. The display device of claim 17, wherein the sealing member comprises:
a first sealing member surrounding at least a portion of the display element layer; and
a second sealing member surrounding at least a portion of the first sealing member.

19. The display device of claim 18, wherein the second sealing member comprises a glass powder and a ceramic filler.

20. The display device of claim 17, wherein the acidic material comprises at least one selected from a group consisting of a methacrylic acid, an acrylic acid, and a citric acid.

21. An electronic device comprising:
a processor configured to output an image data signal and an input control signal; and
a display device configured to drive based on the image data signal and the input control signal, and including:
a first substrate;
a display element layer disposed on the first substrate and comprising at least one pixel comprising a quantum dot;
a first sealing member disposed on the first substrate and surrounding at least a portion of the display element layer;
a second sealing member disposed on the first substrate and surrounding at least a portion of the first sealing member; and
a second substrate disposed on the display element layer, the first sealing member, and the second sealing member.

22. The electronic device of claim 21, further comprising:
a sensor module electrically connected to the processor.

23. The electronic device of claim 22, wherein the sensor module includes at least one selected from a group consisted of an optical sensor module, a touch sensor module, an acceleration sensor module, proximity sensor module, a pupil sensor module, an infrared sensor module, a light sensor module, and an optical sensor module.
